(19) United States
(12) Patent Application Publication
(10) Pub. No.: US 2026/0157009 A1
(43) Pub. Date: Jun. 4, 2026

(54) DISPLAY PANEL AND DISPLAY DEVICE

(71) Applicant: Tianma Advanced Display Technology Institute (Xiamen) Co., Ltd., Xiamen (CN)

(72) Inventors: Xiaoli LIU, Xiamen (CN); Mengmeng XIE, Xiamen (CN); Meng WANG, Xiamen (CN); Ankang SHEN, Xiamen (CN)

(73) Assignee: Tianma Advanced Display Technology Institute (Xiamen) Co., Ltd., Xiamen (CN)

(21) Appl. No.: 19/430,821

(22) Filed: Dec. 23, 2025

(30) Foreign Application Priority Data
Aug. 29, 2025 (CN) 202511231872.3

(51) Int. Cl. H10H 29/855; H10H 29/854; H10K 59/80

(52) U.S. Cl. CPC H10H 29/8552; H10K 59/8792; H10H 29/854; H10K 59/873

(57) ABSTRACT

A display panel includes a first area, a second area, a light-emitting layer, a first organic encapsulation layer, and a light-shielding layer. The light-emitting layer includes insulating layers. The first area includes a part of the insulating layers, and the second area does not include the part of the insulating layers. The first organic encapsulation layer is located on a side of the light-emitting layer and encapsulates the light-emitting device in the light-emitting layer. The light-shielding layer is located on a side of the first organic encapsulation layer away from the light-emitting layer. The light-shielding layer includes hollow portions exposing the light-emitting device. The first edge adjacent to the second area in the first organic encapsulation layer is located on a side of a boundary of the first area and the second area away from the second area.

### CROSS-REFERENCE TO RELATED APPLICATION

The present application claims priority to Chinese Patent Application No. 202511231872.3, filed on Aug. 29, 2025, the content of which is incorporated herein by reference in its entirety.

### TECHNICAL FIELD

The present disclosure relates to the field of display technologies, and in particular, to a display panel and a display device.

### BACKGROUND

In order to prevent a light-emitting device in a display panel from being damaged by external forces or pollutants in subsequent processes, the light-emitting device needs to be encapsulated by an encapsulation layer. In order to ensure an encapsulation effect and ensure that the display panel can normally emit light for display, the encapsulation layer is usually a transparent optical adhesive. In addition, after the manufacturing process of packaging the light-emitting device by using the optical adhesive, a light-shielding layer is further prepared to reduce ambient light entering the display panel, thereby reducing reflection of ambient light by the display panel, and improving contrast of the display panel.

However, since the encapsulation layer usually has a relatively large thickness, the step of an edge of the encapsulation layer is relatively large, which results in a poor process after the encapsulation layer overflows beyond the light-shielding layer, for example, the light-shielding layer overflows to a step area, which causes poor binding between a pin in the step area and a circuit board.

### SUMMARY

An aspect of the present disclosure provides a display panel. The display panel includes a first area, a second area, a light-emitting layer, a first organic encapsulation layer, and a light-shielding layer. The second area is located on a side of the first area adjacent to an edge of the display panel. The first area includes an outer boundary adjacent to the second area. The light-emitting layer includes an array layer and a light-emitting device layer. The array layer includes a plurality of driving devices. The light-emitting device layer includes a plurality of light-emitting devices located in the first area. The light-emitting layer further includes a plurality of insulating layers. The first area includes a part of the insulating layers, and the second area does not include the part of the insulating layers. The first organic encapsulation layer is located on a side of the light-emitting device layer away from the array layer. The first organic encapsulation layer encapsulates the plurality of light-emitting devices. The light-shielding layer is located on a side of the first organic encapsulation layer away from the light-emitting layer. The light-shielding layer includes a plurality of hollow portions exposing the light-emitting device. The first organic encapsulation layer includes a first edge adjacent to the second area. The first edge is located on a side of the outer boundary away from the second area. A distance between the first edge and the outer boundary is d, where d>0.

Another aspect of the present disclosure provides a display device. The display device includes a display panel. The display panel includes a first area, a second area, a light-emitting layer, a first organic encapsulation layer, and a light-shielding layer. The second area is located on a side of the first area adjacent to an edge of the display panel. The first area includes an outer boundary adjacent to the second area. The light-emitting layer includes an array layer and a light-emitting device layer. The array layer includes a plurality of driving devices. The light-emitting device layer includes a plurality of light-emitting devices located in the first area. The light-emitting layer further includes a plurality of insulating layers. The first area includes a part of the insulating layers, and the second area does not include the part of the insulating layers. The first organic encapsulation layer is located on a side of the light-emitting device layer away from the array layer. The first organic encapsulation layer encapsulates the plurality of light-emitting devices. The light-shielding layer is located on a side of the first organic encapsulation layer away from the light-emitting layer. The light-shielding layer includes a plurality of hollow portions exposing the light-emitting device. The first organic encapsulation layer includes a first edge adjacent to the second area. The first edge is located on a side of the outer boundary away from the second area. A distance between the first edge and the outer boundary is d, where d>0.

### BRIEF DESCRIPTION OF DRAWINGS

In order to more clearly explain the embodiments of the present disclosure or the technical solution in the related art, the drawings to be used in the description of the embodiments or the related art will be briefly described below. The drawings in the following description are some embodiments of the present disclosure. For those skilled in the art, other drawings may also be obtained based on these drawings.

FIG. 1 is a schematic diagram of a display panel according to an embodiment of the present disclosure;

FIG. 2 is a cross-sectional view taken along line M1-M2 shown in FIG. 1 according to an embodiment of the present disclosure;

FIG. 3 is a schematic diagram showing a partial structure of a display panel according to an embodiment of the present disclosure;

FIG. 4 is a schematic diagram showing light leakage in the related art;

FIG. 5 is a schematic diagram of an effect of a display panel according to an embodiment of the present disclosure;

FIG. 6 is a schematic diagram showing a partial structure of a display panel according to an embodiment of the present disclosure;

FIG. 7 is a schematic diagram showing a partial structure of a display panel according to an embodiment of the present disclosure;

FIG. 8 is a schematic diagram showing a partial structure of a display panel according to an embodiment of the present disclosure;

FIG. 9 is a schematic diagram showing a partial structure of a display panel according to an embodiment of the present disclosure;

FIG. 10 is a partial cross-sectional view of a partial structure of a display panel according to an embodiment of the present disclosure;

FIG. 11 is a partial cross-sectional view of a partial structure of a display panel according to an embodiment of the present disclosure;

FIG. 12 is a partial cross-sectional view of a partial structure of a display panel according to an embodiment of the present disclosure;

FIG. 13 is a schematic diagram showing a partial structure of a display panel according to an embodiment of the present disclosure;

FIG. 14 is a schematic diagram of a mask plate corresponding to the structure shown in FIG. 13 according to an embodiment of the present disclosure;

FIG. 15 is a schematic diagram showing a partial structure of a display panel according to an embodiment of the present disclosure;

FIG. 16 is a schematic diagram showing a partial structure of a display panel according to an embodiment of the present disclosure;

FIG. 17 is a cross-sectional view taken along line N1-N2 in FIG. 16 according to an embodiment of the present disclosure;

FIG. 18 is a schematic diagram of a mask plate corresponding to the structure shown in FIG. 16 according to an embodiment of the present disclosure;

FIG. 19 is a schematic diagram showing a partial structure of a display panel according to an embodiment of the present disclosure;

FIG. 20 is a partial cross-sectional view of a display panel according to an embodiment of the present disclosure;

FIG. 21 is a partial cross-sectional view of a display panel according to an embodiment of the present disclosure;

FIG. 22 is a schematic diagram of a display device according to an embodiment of the present disclosure; and

FIG. 23 is a schematic diagram of a display device according to another embodiment of the present disclosure.

### DESCRIPTION OF EMBODIMENTS

In order to better understand technical solutions of the present disclosure, the embodiments of the present disclosure are described in details with reference to the drawings.

It should be clear that the described embodiments are merely part of the embodiments of the present disclosure rather than all of the embodiments. All other embodiments obtained by those skilled in the art shall fall into the protection scope of the present disclosure.

The terms used in the embodiments of the present disclosure are merely for the purpose of describing specific embodiment, rather than limiting the present disclosure. The terms “a”, “an”, “the” and “said” in a singular form in the embodiment of the present disclosure and the attached claims are also intended to include plural forms thereof, unless noted otherwise.

It should be understood that the term “and/or” used in the context of the present disclosure is to describe a correlation relation of related objects, indicating that there may be three relations, e.g., A and/or B may indicate only A, both A and B, and only B. In addition, the symbol “/” in the context generally indicates that the relation between the objects in front and at the back of “/” is an “or” relationship.

In this specification, it should be understood that the terms “basically”, “approximately”, “roughly”, “about”, “generally” and “substantially” described in the claims and embodiments of this disclosure refer to a reasonable process operation range or tolerance range, which can be substantially agreed, rather than an exact value.

It should be understood that although the terms ‘first’ and ‘second’ may be used in the present disclosure to describe touch electrodes, these touch electrodes should not be limited to these terms. These terms are used only to distinguish the areas from each other. For example, without departing from the scope of the embodiments of the present disclosure, a first area may also be referred to as a second area. Similarly, the second area may also be referred to as the first area.

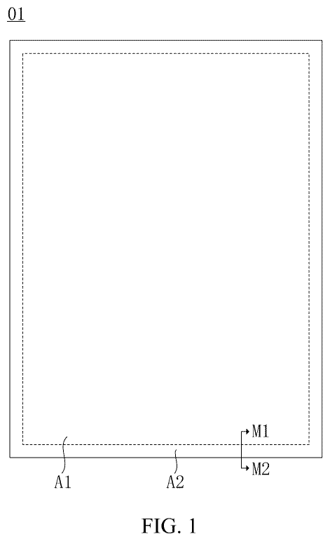

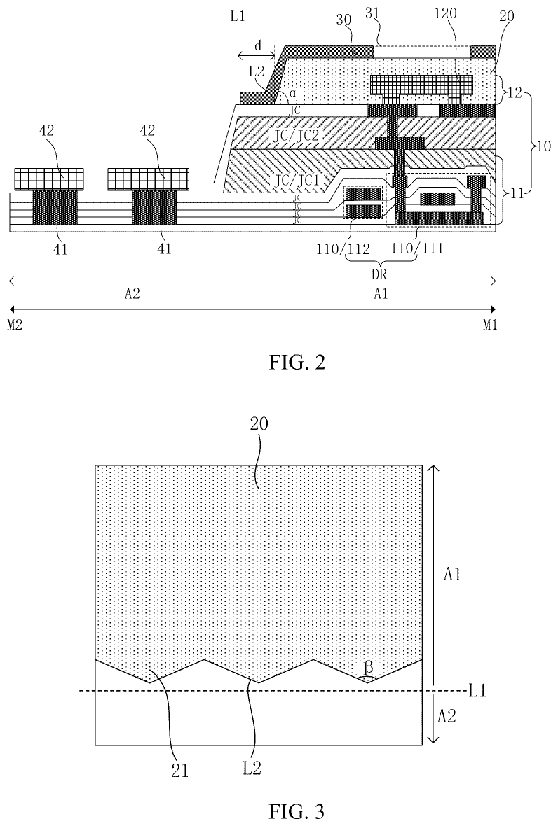

FIG. 1 is a schematic diagram of a display panel according to an embodiment of the present disclosure, and FIG. 2 is a cross-sectional view taken along line M1-M2 shown in FIG. 1 according to an embodiment of the present disclosure.

The present disclosure provides a display panel 01. As shown in FIG. 1, the display panel 01 includes a first area A1 and a second area A2. The second area A2 is located on a side of the first area A1 adjacent to an edge of the display panel 01. The second area A2 may be regarded as an edge area of the display panel 01, and an edge of the second area A2 away from the first area A1 may also coincide with an edge of the display panel 01. The first area A1 may be a display area for light-emitting display, the second area A2 may be a frame area in which peripheral circuits and peripheral wires are disposed, and the display panel 01 may be a narrow-frame display panel, in this case, the second area A2 for arranging frame circuits and peripheral wirings has a relatively narrow width, when a width of the second area A2 is relatively narrow and hardly perceptible to human eyes, the display panel 01 may be regarded as a frame-less display panel.

Referring to FIG. 1 and FIG. 2, the display panel 01 includes a light-emitting layer 10, a first organic encapsulation layer 20 and a light-shielding layer 30. The light-emitting layer 10 is a composite layer including an array layer 11 and a light-emitting device layer 12 and configured to realize light-emitting display. The first organic encapsulation layer 20 is located on a side of the light-emitting device layer 12 away from the array layer 11 and configured to encapsulate and protect the light-emitting device layer 12. The light-shielding layer 30 is located on a side of the first organic encapsulation layer 20 away from the light-emitting layer 10.

The array layer 11 includes a plurality of driving devices 110. The light-emitting device layer 12 includes a plurality of light-emitting devices 120. The driving device 110 may be configured to the light-emitting device 120 for light-emitting display. The light-emitting device 120 may be an organic light-emitting diode (OLED), and in this case, the light-emitting device 120 may be prepared by a process such as evaporation. Further, the light-emitting device 120 may be a sub-millimeter light-emitting diode, a micro-LED, or the like, and in this case, the light-emitting device 120 may be electrically connected to the driving device 110 in the array layer 11 by means of plugging, welding, adhesive, bonding, or the like. The light-emitting device 120 is located in the first area A1. The first area A1 may be a display area in the display panel 01. A portion of the array layer 11 located in the first area A1 may include a driving device 110 such as a pixel circuit DR. The pixel circuit DR may include a transistor 111, a capacitor 112, and the like. The pixel circuit DR may be electrically connected to the light-emitting device 120 and drive the light-emitting device 120 to emit light. A portion of the array layer 11 located in the second area A2 may include the driving device 110 such as a shift register and a multiplexer switch (not shown).

The first organic encapsulation layer 20 is located on a side of the light-emitting device layer 12 away from the array layer 11, and may be considered as being located on a side of the light-emitting device layer 12 facing the light-emitting surface of the display panel 01. Therefore, the first organic encapsulation layer 20 may be a transparent structure. When the first organic encapsulation layer 20 is a transparent structure, the light emitted by the light-emitting device 120 may exit from the light-emitting surface of the display panel 01 after passing through the first organic encapsulation layer 20. The first organic encapsulation layer 20 encapsulates the light-emitting device 120 and is configured to protect the light-emitting device 120, which may prevent the light-emitting device 120 from wearing by subsequent processes, and may also prevent external water and oxygen from invading into the light-emitting device 120 and the array layer 11 to corrode the light-emitting device 120. The first organic encapsulation layer 20 may be prepared from a transparent optical adhesive, and a process for preparing the first organic encapsulation layer 20 may be coating, inkjet printing, or the like.

The light-shielding layer 30 is located on a side of the first organic encapsulation layer 20 away from the light-emitting layer 10, the light-shielding layer 30 is prepared after the first organic encapsulation layer 20 is formed, and at least the first organic encapsulation layer 20 in the first area A1 may provide a relatively flat bearing surface for the light-shielding layer 30. The light-shielding layer 30 includes a plurality of hollow portions 31, and the hollow portions 31 expose the light-emitting device 120, so as to ensure that light emitted by the light-emitting device 120 may be emitted from the light-shielding layer 30 through the hollow portion 31. The periphery of the hollow portion 31 may be a solid portion in the light-shielding layer 30. That is, the periphery of the hollow portion 31 may be the light-shielding portion. A projection of the light-shielding portion along the direction perpendicular to the plane of the display panel 01 may overlap with the area between adjacent light-emitting devices 120, and the light-shielding portion may improve the problem of light crosstalk when the light of different light-emitting devices 120 exits from a side of the light-emitting surface of the display panel 01. In an embodiment, a color resist (not shown) may be filled in the hollow portion 31, and the color resist may filter the light emitted by the light-emitting device 120 below the hollow portion 31 to ensure the color purity of the emitted light. Meanwhile, the ambient light to be incident on the display panel 01 may also be filtered to reduce the reflection of the ambient light on the light-emitting device layer 12 and the array layer 11, thereby improving the reflection problem of the display panel 01 on the ambient light and improving the contrast of the display panel 01.

The light-emitting layer 10 further includes a plurality of insulating layers JC. A part of the insulating layers JC is included in the first area A1, and this part of the insulating layer JC is not included in the second area A2. That is, the part of the insulating layers JC included in the light-emitting layer 10 are cut off near a boundary position between the second area A2 and the first area A1, as shown in FIG. 2, near the boundary position between the first area A1 and the second area A2, the light-emitting layer 10 forms a step structure in which a first area A1 is thick and a thin second area A2 is thin. Still referring to FIG. 2, the first area A1 includes an outer boundary L1 adjacent to the second area A2, the outer boundary L1 may be regarded as a boundary between the first area A1 and the second area A2, and the part of the insulating layers JC included in the light-emitting layer 10 are cut off near the outer boundary L1 to form the step structure. For example, the insulating layer JC between the light-emitting device layer 12 and the array layer 11 includes a first planarization layer JC1 and a second planarization layer JC2, and the first planarization layer JC1 and the second planarization layer JC2 are located in the first area A1 and are not disposed in the second area A2. That is, the first planarization layer JC1 and the second planarization layer JC2 are cut off in the second area A2. It should be noted that a side surface of the insulating layer JC cut off in the second area A2 is usually a surface with a certain inclination angle, which results in that a side surface of the step structure is a surface with a certain inclination angle. The side surface with a certain inclination angle is caused by process precision limitation such as etching. That is, the insulating layer JC that should be cut off at the boundary position between the first area A1 and the second area A2 may remain in a part of the second area A2 due to process precision limitation, so that the position of an upper edge of the step structure may be regarded as the outer boundary L1. For example, the second planarization layer JC2 is located on a side of the first planarization layer JC1 adjacent to the first organic encapsulation layer 20, and side surfaces of the first planarization layer JC1 and the second planarization layer JC2 are both inclined surfaces. Therefore, an edge of an upper surface of the second planarization layer JC2 may be regarded as the outer boundary L1.

It should be noted that FIG. 2 only shows a possible stacking structure of the first area A1, and in other embodiments, other stacking structures may also be used, which is not limited in the present disclosure.

The first organic encapsulation layer 20 includes a first edge L2 adjacent to the second area A2. The first edge L2 may be regarded as an edge of the first organic encapsulation layer 20 facing the second area A2, and the first organic encapsulation layer 20 is also cut off before reaching the second area A2. In some embodiments of the present disclosure, the first edge L2 is located on a side of the outer boundary L1 away from the second area A2, and a distance between the first edge L2 and the outer boundary L1 is d, d>0. Therefore, an edge of the first organic encapsulation layer 20 retracts in a direction away from the second area A2 relative to the boundary between the first area A1 and the second area A2. That is, the first organic encapsulation layer 20 retracts toward a position away from the above step structure in the first area A1.

In order to achieve a better encapsulation effect on the light-emitting device 120, a thickness of the first organic encapsulation layer 20 is usually large. For example, when the light-emitting device 120 is a micro light-emitting diode, a total thickness of the light-emitting device 120 and a bonding layer is usually greater than or equal to 10 μm. In order to effectively reduce the damage of external forces and dust to the light-emitting device 120, a thickness of the first organic encapsulation layer 20 is greater than 10 μm. Further, when the display panel 01 is a transparent screen and includes a transparent area except for a plurality of pixel areas, it is necessary to hollow a part of the insulating layers JC in the transparent area to ensure that the transparent area has a higher light transmittance, which causes a step greater than or equal to 16 μm between a upper surface of the light-emitting device 120 and a upper surface of the transparent area, then a thickness of the first organic encapsulation layer 20 needs to be greater than or equal to 18 μm to fill the step to better protect the light-emitting device 120. The first edge L2 of the first organic encapsulation layer 20 has a large height difference, and the light-shielding layer 30 is prepared above the first organic encapsulation layer 20, and the light-shielding layer 30 experiences a large height difference when overflowing to the outside of the first organic encapsulation layer 20, so that the area of the light-shielding layer 30 overflowing to the second area A2 is large, and the second area A2 has a poor process.

According to the present disclosure, by retracting the first organic encapsulation layer 20 in a direction away from the outer boundary L1 in the first area A1, it is equivalent to providing a redundant space between the edge of the first organic encapsulation layer 20 and the outer boundary L1, and when the light-shielding layer 30 overflows beyond the first organic encapsulation layer 20, the light-shielding layer 30 overflows to the redundant space first. Therefore, the probability that the light-shielding layer 30 overflows to the second area A2 is reduced. In addition, even if the light-shielding layer 30 overflows to the second area A2, a thickness of the light-shielding layer 30 in the second area A2 is reduced compared with the related art, and the area of the light-shielding layer 30 in the second area A2 is also reduced compared with the related art, so that the light-shielding layer 30 is easily removed in the subsequent patterning process. According to the technical solution of the present disclosure, the risk of residual light-shielding layer 30 in the second area A2 may be reduced, so that the process defect may be improved.

According to an embodiment of the present disclosure, the second area A2 includes a plurality of pins 41. The pins 41 are electrically connected to the circuit board 42, and the circuit board 42 may be an integrated circuit board (IC) or a flexible circuit board (FPC). For example, the pin 41 adjacent to the first area A1 may be electrically connected to the IC and the pin 41 far away from the first area A1 may be electrically connected to the FPC. In addition, the pin 41 in the first area A1 may also be electrically connected to only the FPC. A signal interaction between a signal line and a driving module in the display panel 01 may be realized by the pin 41, and the second area A2 may be regarded as a step area of the display panel 01.

When the second area A2 is the step area including the pin 41, and when the light-shielding layer 30 overflows to the second area A2, the pin 41 has a risk of being covered by the light-shielding layer 30. When the amount of the light-shielding layer 30 overflows to the second area A2 is larger, the area of the pin 41 covered by the light-shielding layer 30 is larger, and a thickness of the pin 41 is larger. Therefore, due to the existence of the first organic encapsulation layer 20, the area of the pin 41 in the step area in the related art covered by the light-shielding layer 30 is large and the thickness is large, and when the light-shielding layer 30 in the first area A1 is etched to form the hollow portion 31, the possibility that the light-shielding layer 30 above the pin 41 is effectively etched is reduced.

In embodiments of the present disclosure, the first edge L2 of the first organic encapsulation layer 20 is disposed on a side of the outer boundary L1 away from the second area A2, and a distance between the first edge L2 and the outer boundary L1 is greater than 0, so that when the light-shielding layer 30 overflows beyond the first organic encapsulation layer 20, the light-shielding layer 30 may first pass through a redundant space between the first edge L2 and the outer boundary L1. Therefore, an overflow action of the light-shielding layer 30 is slowed down, and at least a part of the overflowed light-shielding layers 30 remain in the redundant space. Therefore, there will be no step area in the overflowed light-shielding layer 30, or a thickness and an area of the light-shielding layer 30 appearing in the step area are reduced. The pin 41 is not covered by the light-shielding layer 30, or, even if the pin 41 is covered by the light-shielding layer 30, the covered area and thickness are both relatively small, and the process of etching the light-shielding layer 30 in the first area A1 to form the hollow portion 31 is easy to simultaneously realize the removal of the light-shielding layer 30 above the pin 41.

The second area A2 may also include an alignment mark. When the light-shielding layer 30 overflows to the second area A2, the alignment mark has a risk of being covered by the light-shielding layer 30. If a thickness of the light-shielding layer 30 covering the alignment mark is thicker, the possibility that the light-shielding layer 30 above the alignment mark is effectively etched is reduced, which affects the accuracy of subsequent alignment, and further affects the yield of the structure prepared by the subsequent process. The present disclosure can effectively reduce the possibility that the light-shielding layer 30 overflows to the alignment mark or reduce the amount of the light-shielding layer 30 overflows to the second area A2, thereby avoiding the problem that the alignment mark is covered by the light-shielding layer 30 and cannot be exposed.

In addition, an edge of the second area A2 may be a cutting line. That is, when the plurality of display panels 01 are obtained by cutting a motherboard, the cutting line coincides with the edge of the second area A2. If the light-shielding layer 30 overflows to the second area A2, the cutting difficulty is increased, and cutting burrs are easily caused, thereby affecting the morphology of the edge of the display panel 01. If the display panel 01 is applied to a splicing screen, it may also further result in an increase in splicing difficulty, inadequate splicing gaps, or splicing gaps that are clearly visible. The present disclosure can effectively reduce the possibility that the light-shielding layer 30 overflows to the position where the cutting line is located or reduce the amount of the light-shielding layer 30 overflows to the position where the cutting line is located, thereby improving the cutting yield.

According to an embodiment of the present application, d≥5 μm. That is, the edge of the first organic encapsulation layer 20 is at least retracted by 5 μm relative to the outer boundary L1. When the edge of the first organic encapsulation layer 20 is at least retracted by 5 μm relative to the outer boundary L1, an obvious redundant space is formed between the edge of the first organic encapsulation layer 20 and the outer boundary L1, thereby slowing down the overflow speed of the light-shielding layer 30 to the second area A2. For example, d=10 μm.

In an embodiment, d≥40 μm. That is, the edge of the first organic encapsulation layer 20 is at least retracted by 40 μm relative to the outer boundary L1, so that the redundant space between the edge of the first organic encapsulation layer 20 and the outer boundary L1 may accommodate more light-shielding layers 30. Therefore, it not only provides the redundant space to slow down the overflow speed of the light-shielding layer 30 to the second area A2, but it also accommodates the light-shielding layer 30 through a sufficiently spacious redundant space, thereby effectively reducing the amount of the light-shielding layer 30 overflows to the second area A2.

According to an embodiment of the present disclosure, the first organic encapsulation layer 20 is a negative photosensitive layer.

When the first organic encapsulation layer 20 is a photosensitive layer, in the process of patterning the first organic encapsulation layer 20, the first organic encapsulation layer 20 may be exposed by using a mask plate and the exposed first organic encapsulation layer 20 is developed by using a developing solution. That is, the patterned first organic encapsulation layer 20 is obtained without using photoresist, thereby omitting processes such as exposure, development, and cleaning of the photoresist. Therefore, when the first organic encapsulation layer 20 is the photosensitive layer, its preparation processes and steps are simple.

The negative photosensitive layer has better corrosion resistance, therefore, when the light-shielding layer 30 including the hollow portion 31 is prepared above the negative light sensing layer, it may still have a relatively flat surface, thereby reducing the influence of the surface morphology change on the light emitted by the light-emitting device 120. In addition, since the thickness of the first organic encapsulation layer 20 is large, when the first organic encapsulation layer 20 is prepared by using the negative photosensitive material, the first organic encapsulation layer 20 with better uniformity and stability may be obtained, and the first organic encapsulation layer 20 has low cost and high mechanical strength.

The inclination angle of the side surface of the first organic encapsulation layer 20 may be configured to be small. That is, the slope of the side surface of the first organic encapsulation layer 20 is slow, so as to slow the overflow speed and the overflow amount of the light-shielding layer 30 to the second area A2. However, since it is difficult for the negative photosensitive layer to achieve high-resolution patterning, optical proximity correction (OPC) technology basically cannot be adopted to make an edge area of the first organic encapsulation layer 20 form a gentle slope.

According to some embodiments of the present disclosure, the edge of the first organic encapsulation layer 20 is retracted relative to the outer boundary L1 to reduce the amount of the subsequently prepared light-shielding layer 30 overflowing to the second area A2. Therefore, in the embodiments of the present disclosure, the first organic encapsulation layer 20 is prepared by using the negative photosensitive material. That is, the advantage of the negative photosensitive layer is utilized, and the problem that the light-shielding layer 30 overflows to the second area A2 is improved by retracting inward the first organic encapsulation layer 20 relative to the outer boundary L1.

According to an embodiment of the present disclosure, as shown in FIG. 2, the inclination angle of the side surface of the first organic encapsulation layer 20 is α, where α<90°. If the side surface of the first organic encapsulation layer 20 is a vertical surface, the speed at which the light-shielding layer 30 overflows to the first organic encapsulation layer 20 will be fast and a risk of breakage of the light-shielding layer 30 on the side surface of the first organic encapsulation layer 20 will be greatly increased. In some embodiments, the side surface of the first organic encapsulation layer 20 is an inclined surface, so that the speed at which the light-shielding layer 30 overflows to the first organic encapsulation layer 20 may be slowed down, thereby avoiding excessive overflow of the light-shielding layer 30 to the second area A2. The problem of breakage of the light-shielding layer 30 near the edge of the first organic encapsulation layer 20 may be relieved, so as to ensure a visual effect near the outer boundary L1.

In an embodiment, the inclination angle of the side surface of the first organic encapsulation layer 20 is α, and 70°≤α<90°. When the inclination of the side surface of the first organic encapsulation layer 20 is greater than or equal to 70°, the area of an orthographic projection of the side surface in the direction perpendicular to the plane of the display panel 01 is relatively small, which avoids the side surface occupying too much space to affect the display effect and visual effect of the display area. In addition, if the first organic encapsulation layer 20 is the negative photosensitive layer, the inclination angle of the side surface of the first organic encapsulation layer 20 is greater than or equal to 70°, which is easy to realize.

According to an embodiment of the present disclosure, as shown in FIG. 2, the light-shielding layer 30 covers the edge of the first organic encapsulation layer 20. When the edge of the first organic encapsulation layer 20 is retracted relative to the outer boundary L1, a distance between the edge of the first organic encapsulation layer 20 and the light-emitting device 120 in the display area is closer, and if the edge of the first organic encapsulation layer 20 is not covered by the light-shielding layer 30, the metal structure in the light-emitting device 120 near the edge of the display area and the metal structure near the light-emitting device 120 such as the signal line will reflect light, and thus be perceived by the human eyes, affecting the visual effect. According to an embodiment of the present disclosure, although the first organic encapsulation layer 20 is designed to be retracted, making the light-shielding layer 30 cover the edge of the first organic encapsulation layer 20 may improve the problems of light leakage and visible metal structure in the area where the edge of the first organic encapsulation layer 20 is located. It should be noted that the side surface of the first organic encapsulation layer 20 may be an inclined surface, so an edge of the upper surface of the first organic encapsulation layer 20 does not overlap an edge of the lower surface of the first organic encapsulation layer 20. The light-shielding layer 30 covering the edge of the first organic encapsulation layer 20 may be understood as the light-shielding layer 30 covering the edge of the upper surface, the edge of the lower surface, and the side surfaces of the first organic encapsulation layer 20.

FIG. 3 is a schematic diagram showing a partial structure of a display panel according to an embodiment of the present disclosure.

According to an embodiment of the present disclosure, as shown in FIG. 3, the first edge L2 includes a first protrusion 21, the first protrusion 21 protrudes away from the first area A1, and the first protrusion 21 may be regarded as a structure in which the first organic encapsulation layer 20 protrudes from the first area A1 to the second area A2. When the first edge L2 includes a plurality of first protrusions 21, the shape of the first edge L2 may be regarded as a curve or a broken line.

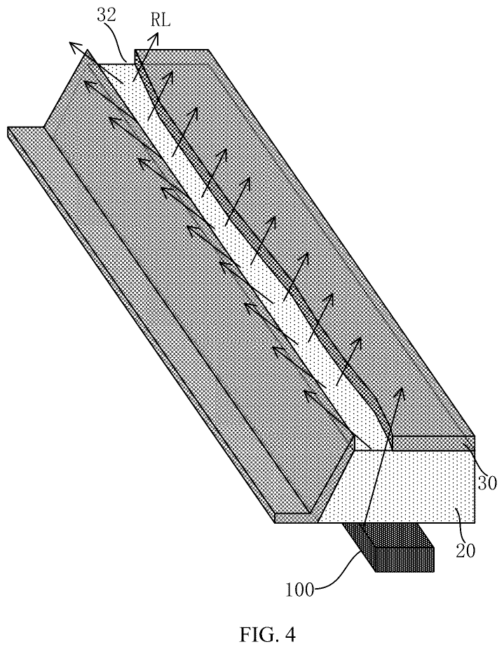

FIG. 4 is a schematic diagram showing light leakage in the related art.

The light-shielding layer 30 may have a similar climbing phenomenon on the side surface of the first organic encapsulation layer 20, and a risk that the light-shielding layer 30 on the side surface of the first organic encapsulation layer 20 breaks to form a crack 32 is relatively high. In addition, when the light-shielding layer 30 is prepared, the light-shielding layer 30 may overflow from the upper surface of the first organic encapsulation layer 20 to the second area A2 through the side surface of the first organic encapsulation layer 20, the edge of the light-shielding layer 30 on the upper surface of the first organic encapsulation layer 20 may be thinned or even broken, and when the light-shielding layer 30 is subsequently etched, a risk that the light-shielding layer 30 at the edge position of the upper surface of the first organic encapsulation layer 20 is etched away and a crack 32 occurs is increased. As shown in FIG. 4, since the first edge L2 of the first organic encapsulation layer 20 is designed to be retracted toward the display area, the possibility that metal structures 100 included in the light-emitting device 120 and the signal line near the area where the edge of the first organic encapsulation layer 20 is located overlaps the crack 32 is increased. If the crack 32 overlaps the metal structures 100, light RL reflected by the metal structures 100 is visible to human eyes through the crack 32 of the light-shielding layer 30. That is, the metal structures 100 overlapping the crack 32 is obviously visible, thereby affecting the visual effect. When the light-shielding layer 30 has the crack 32 on the side surface of the first organic encapsulation layer 20 and/or the crack 32 on the edge of the upper surface of the first organic encapsulation layer 20, an extension direction of the crack 32 is substantially consistent with an extension direction of the edge of the first organic encapsulation layer 20, and since the metal structures such as the signal line below usually extends in a straight line, the human eyes may easily perceive an obvious bright line. That is, the metal structures 100 overlapping the crack 32 may be clearly seen.

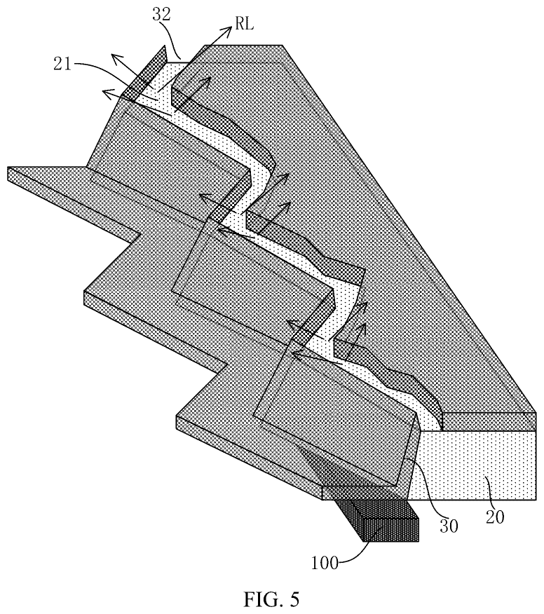

FIG. 5 is a schematic diagram of an effect of a display panel according to an embodiment of the present disclosure.

According to an embodiment of the present disclosure, the first edge L2 of the first organic encapsulation layer 20 is configured to include the first protrusion 21, so that the visibility of the reflected light is reduced, a shadow elimination of the metal structure 100 is realized, and the visual effect is improved. As shown in FIG. 5, when the first edge L2 includes a plurality of first protrusions 21, since the extending direction of the cracks 32 is substantially the same as the extending direction of the edge of the first organic encapsulation layer 20, even if the light-shielding layer 30 on the side surface of the first organic encapsulation layer 20 has continuous cracks 32, or the light-shielding layer 30 near the edge position of the upper surface of the first organic encapsulation layer 20 has continuous cracks 32, the extending directions of the cracks 32 are substantially broken lines or curves. The area where the crack 32 overlaps the metal structure 100 extending substantially along the straight line is not a continuous structure, but a dot-like structure, so that the problem that the reflected light passing through the crack 32 is obviously visible is solved, the problem that the metal structure 100 is obviously seen through the crack 32 is also solved, and the visual effect of the display panel 01 is improved.

As shown in FIG. 3, an angle of an inner angle of the first protrusion 21 may be β, where β≥150°. An inner angle of the first protrusion 21 is an angle facing an opening of the first area A1. When an angle of the inner angle β of the first protrusion 21 is greater than or equal to 150°, the first protrusion 21 is easily prepared by processes such as etching. In addition, when the angle of the inner angle β of the first protrusions 21 is greater than or equal to 150°, a width of the first protrusions 21 in a direction parallel to the extending direction of the outer boundary L1 is relatively large, which reduces a distance between the breakage position of the light-shielding layer 30 and the area where the metal structures extending in a straight line overlap, further weakening the visibility of the reflected light. In addition, when the inner angle β of the first protrusion 21 is larger, a width of the first protrusion 21 protruding from the first area A1 toward the second area A2 may be narrower, and on the premise of avoiding the first protrusion 21 from affecting the display effect of the display area, the edge of the first organic encapsulation layer 20 has the opportunity to retract by a larger width relative to the outer boundary L1, thereby effectively improving the overflow problem of the light-shielding layer 30.

FIG. 6 is a schematic diagram showing a partial structure of a display panel according to an embodiment of the present disclosure.

In an embodiment, as shown in FIG. 6, the first protrusion 21 overlaps the light-emitting device 120 in a first direction X, the first direction X is parallel to the direction of the plane of the display panel 01 and is parallel to an arrangement direction of the first area A1 and the second area A2, so that orthographic projections of the first protrusion 21 and the light-emitting device 120 in the direction perpendicular to the plane of the display panel 01 are arranged in the first direction X, and at this time, the orthographic projections of the two may partially overlap. That is, the first protrusion 21 is located between the area where the light-emitting device 120 is located and the second area A2 along the arrangement direction of the first area A1 and the second area A2, or the first protrusion 21 protrudes from a position near a position where the light-emitting device 120 is located to a position where the second area A2 is located.

In this technical solution, an area between the light-emitting device 120 near the edge of the display area and the second area A2 includes the first protrusion 21 of the first organic encapsulation layer 20, and referring to FIG. 5 and FIG. 6, if the light-shielding layer 30 has the crack 32 near the edge of the first organic encapsulation layer 20, the crack 32 between the light-emitting device 120 near the edge of the display area and the second area A2 may be further away from the light-emitting device 120 due to the arrangement of the first protrusion 21. On the one hand, the probability that the crack 32 overlaps the light-emitting device 120 is reduced as possible, so as to prevent the structures reflecting light such as eutectic alloy corresponding to the light-emitting device 120 from reflecting light to the light-emitting surface of the display panel 01 through the crack 32 as possible. On the other hand, when the edge of the first organic encapsulation layer 20 is patterned to form the first protrusion structure 21, the farther the distance between the edge of a hollow area of the mask plate and the light-emitting device 120 is, the lower the risk that the structure reflecting light such as eutectic alloy corresponding to the light-emitting device 120 reflects the exposed light to the position not needing to be exposed, and the lower the risk that the first organic encapsulation layer is over-etched or error-etched. In order to better achieve the above effect, a distance between the end of the first protrusion 21 adjacent to the second area A2 and the light-emitting device 120 may be greater than or equal to 5 μm, for example, it may be 10 μm.

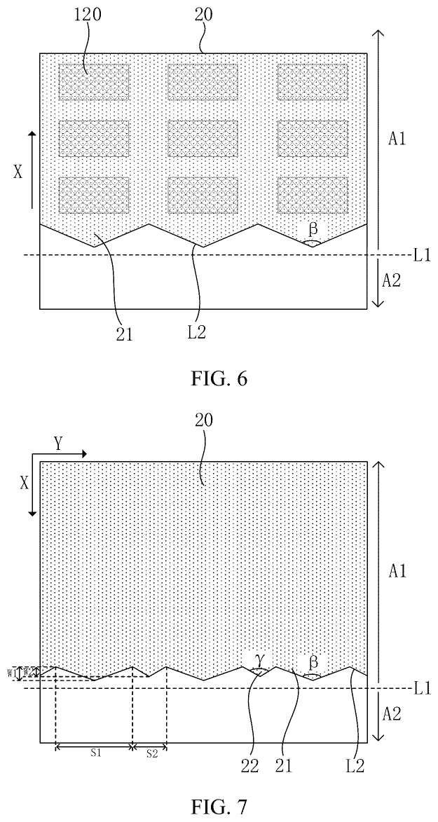

FIG. 7 is a schematic diagram showing a partial structure of a display panel according to an embodiment of the present disclosure.

According to an embodiment of the present disclosure, as shown in FIG. 7, the first edge L2 not only includes the first protrusion 21, but also includes the second protrusion 22, the second protrusion 22 protrudes away from the position where the first area A1 is located, and the morphology of the second protrusion 22 is different from the morphology of the first protrusion 21. The second protrusion 22 may be regarded as a structure in which the first organic encapsulation layer 20 protrudes from the first area A1 to the second area A2 and is different from the first protrusion 21. The morphology of the second protrusion 22 is different from the morphology of the first protrusion 21 may mean that between an orthographic projection of the second protrusion 22 along the direction perpendicular to the plane of the display panel 01 and an orthographic projection of the first protrusions 21 in the direction perpendicular to the plane of the display panel 01, their shapes are the same but their sizes are different, or their shapes are different. Their shapes are different, which may refer to that the shapes of the two are different, for example, one is triangular and the other is semicircular; or may refer to that the shapes of the two are the same, but the angles or side length are different, for example, both are triangular and the inner angle of one is greater than the inner angle of the other, or both are triangular and the side lengths of the two are different.

The arrangement of the second protrusion 22 can also solve the problem that the reflected light is obviously visible due to the breakage of the light-shielding layer 30 near the edge of the first organic encapsulation layer 20. In addition, since the morphology of the second protrusion 22 is different from the morphology of the first protrusion 21, the extending direction of the crack 32 formed by the breakage near the edge position of the first organic encapsulation layer 20 of the light-shielding layer 30 is more variable, so that the overlapping position of the metal structures 100 and the like capable of reflecting light below the light-shielding layer 30 is more variable to reduce the possibility that the light reflected by the metal structures 100 passes through the crack 32 to form an obvious bright line. That is, the shadow elimination effect on the metal structures 100 is further improved.

In an embodiment, as shown in FIG. 7, the inner angle of the second protrusion 22 may be γ, where γ≤β. That is, the inner angle γ of the second protrusion 22 may be less than or equal to the inner angle β of the first protrusion 21. Therefore, the first edge L2 of the first organic encapsulation layer 20 may include protrusions with different inner angles, so that the extending direction of the crack 32 formed by the breakage near the edge position of the first organic encapsulation layer 20 of the light-shielding layer 30 is more variable, and the overlapping position of the metal structures 100 and the like capable of reflecting light below the light-shielding layer 30 is more variable, thereby improving the shadow elimination effect on the metal structures 100.

In an embodiment, as shown in FIG. 7, a width W2 of the second protrusion 22 in a second direction Y is less than a width W1 of the first protrusion 21 in the second direction Y, and the second direction Y is perpendicular to the first direction X. Therefore, the first edge L2 of the first organic encapsulation layer 20 may include protrusions with different width, so that the extending direction of the crack 32 formed by the breakage near the edge position of the first organic encapsulation layer 20 of the light-shielding layer 30 is more variable, and the overlapping position of the metal structures 100 and the like capable of reflecting light below the light-shielding layer 30 is more variable, thereby improving the shadow elimination effect on the metal structures 100.

In an embodiment, as shown in FIG. 7, a length S2 of the second protrusion 22 in the first direction X is less than a length S1 of the first protrusion 21 in the first direction X. That is, a height of the second protrusion 22 protruding from the first area A1 to the second area A2 is less than a height of the first protrusion 21 protruding from the first area A1 to the second area A2. Therefore, the first edge L2 of the first organic encapsulation layer 20 may include protrusions with different widths, so that the extending direction of the crack 32 formed by the breakage near the edge position of the first organic encapsulation layer 20 of the light-shielding layer 30 is more variable, and the overlapping position of the metal structures 100 and the like capable of reflecting light below the light-shielding layer 30 is more variable, thereby improving the shadow elimination effect on the metal structures 100.

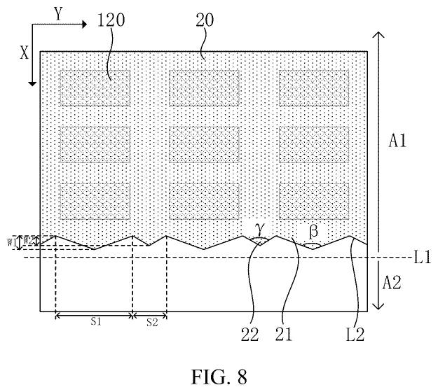

FIG. 8 is a schematic diagram showing a partial structure of a display panel according to an embodiment of the present disclosure.

In an embodiment, as shown in FIG. 8, the second protrusion 22 is misaligned with the light-emitting device 120 in the first direction X. That is, the second protrusion 22 protrudes from an area between adjacent light-emitting devices 120 in the first area A1 to the second area A2. Therefore, the first edge L2 of the first organic encapsulation layer 20 includes the first protrusion 21 overlapping the light-emitting device 120 in the first direction X, and further includes the second protrusion 22 not overlapping the light-emitting device 120 in the first direction X, so that the protrusion may be effectively used to remove the shadow from the metal structures 100.

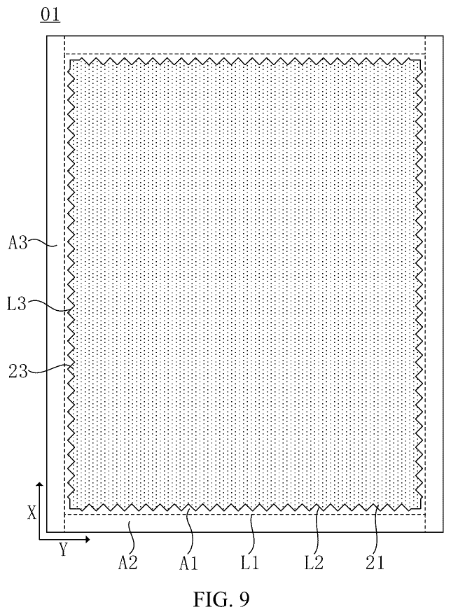

FIG. 9 is a schematic diagram showing a partial structure of a display panel according to an embodiment of the present disclosure.

According to an embodiment of the present disclosure, as shown in FIG. 9, the display panel 01 further includes a third area A3. The first organic encapsulation layer 20 further includes a second edge L3 adjacent to the third area A3. The second edge L3 includes a third protrusion 23. The third protrusion 23 protrudes in the second direction Y to a position away from the first area A1. The third area A3 and the first area A1 are arranged in the second direction Y, and the second area A2 and the first area A1 are arranged in the first direction X. Therefore, a shape of the second edge L3 may be regarded as a curve or a broken line, which may reduce the problem that the metal structures 100 near the second edge L3 is visible due to the crack 32 of the light-shielding layer 30.

In addition, the second edge L3 may further include other protrusions have the morphology different from the morphology of the third protrusion 23.

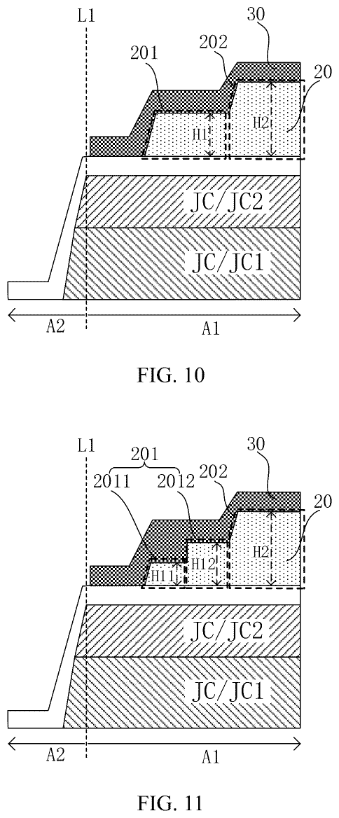

FIG. 10 is a partial cross-sectional view of a partial structure of a display panel according to an embodiment of the present disclosure.

According to an embodiment of the present disclosure, as shown in FIG. 10, the first organic encapsulation layer 20 includes a first portion 201 and a second portion 202, the second portion 202 is located in the first area A1, and the first portion 201 is located on a side of the second portion 202 facing the second area A2. That is, the first portion 201 is closer to the edge of the first organic encapsulation layer 20 than the second portion 202. The second portion 202 may be regarded as a main body portion of the first organic encapsulation layer 20, and the first portion 201 may be regarded as an edge portion of the first organic encapsulation layer 20 adjacent to the second area A2.

A thickness of the first portion 201 is H1, a thickness of the second portion 202 is H2, where H1<H2, and the thickness of the first portion 201 is less than the thickness of the second portion 202. That is, the thickness of the edge portion of the first organic encapsulation layer 20 adjacent to the second area A2 has been subjected to a thinning design relative to the main body portion of the first organic encapsulation layer 20. Through the thinning design, the speed at which the light-shielding layer 30 overflows beyond the first organic encapsulation layer 20 may be slowed down, the speed at which the light-shielding layer 30 overflows to the second area A2 is also slowed down. This further reduces the amount and area of the light-shielding layer 30 that overflows to the second area A2, which facilitates the subsequent removal of the light-shielding layer 30 in the second area A2.

FIG. 11 is a partial cross-sectional view of a partial structure of a display panel according to an embodiment of the present disclosure.

According to an embodiment of the present disclosure, as shown in FIG. 11, the first portion 201 includes a first sub-portion 2011 and a second sub-portion 2012. The first sub-portion 2011 is located on a side of the second sub-portion 2012 facing the second area A2, a thickness of the first sub-portion 2011 is H11, a thickness of the second sub-portion 2012 is H12, and H11 is less than H12. That is, the thickness of the first sub-portion 2011 is less than the thickness of the second sub-portion 2012. That is, the edge portion of the first organic encapsulation layer 20 adjacent to the second area A2 is also a structure similar to a step, and the speed at which the light-shielding layer 30 overflows beyond the first organic encapsulation layer 20 may be further buffered.

According to an embodiment of the present disclosure, as shown in FIG. 10 and FIG. 11, a surface of the first portion 201 away from the light-emitting layer 10 may be a flat surface. Since the edge of the first organic encapsulation layer 20 retracts so that the distance between the edge portion of the first organic encapsulation layer 20 and the light-emitting device 120 in the display area is closer, if at least a part of the light emitted by the light-emitting device 120 located at the edge portion in the display area is emitted through the first portion 201, and the surface of the first portion 201 away from the light-emitting layer 10 is the flat surface, the influence of the light emitted through the first portion 201 on the surface morphology of the first portion 20 may be avoided as possible.

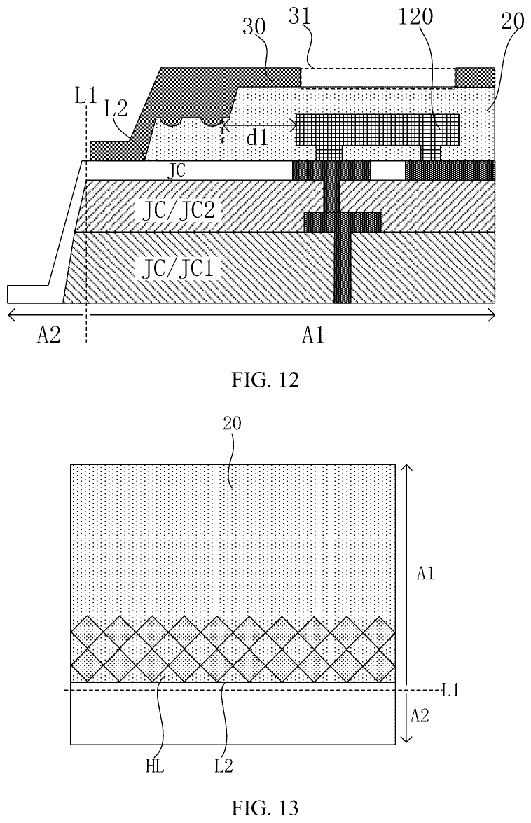

FIG. 12 is a partial cross-sectional view of a partial structure of a display panel according to an embodiment of the present disclosure.

According to an embodiment of the present disclosure, as shown in FIG. 12, a surface of the first portion 201 away from the light-emitting layer 10 includes a plurality of grooves HL, so an upper surface of the first portion 201 for bearing the light-shielding layer 30 includes a plurality of grooves HL. A part of the light-shielding layer 30 may be accommodated in the grooves HL, which may reduce the amount of the light-shielding layer 30 overflowing beyond the first organic encapsulation layer 20; in addition, the second groove may also provide an obstacle for the light-shielding layer 30 overflowing beyond the first organic encapsulation layer 20, and slow down the speed at which the light-shielding layer 30 overflowing beyond the first organic encapsulation layer 20.

In an embodiment, as shown in FIG. 12, a distance between the groove HL and the light-emitting device 120 is d1 in the direction parallel to the plane of the display panel 01, d1≥5 μm. That is, the distance between the groove HL and the light-emitting device 120 is greater than or equal to 5 μm. By disposing the groove HL outside 5 μm of the position where the light-emitting device 120 is located, the groove HL may be prevented from overlapping the light-emitting device 120, so as to reduce the influence of the groove HL on the light emitted by the light-emitting device 120.

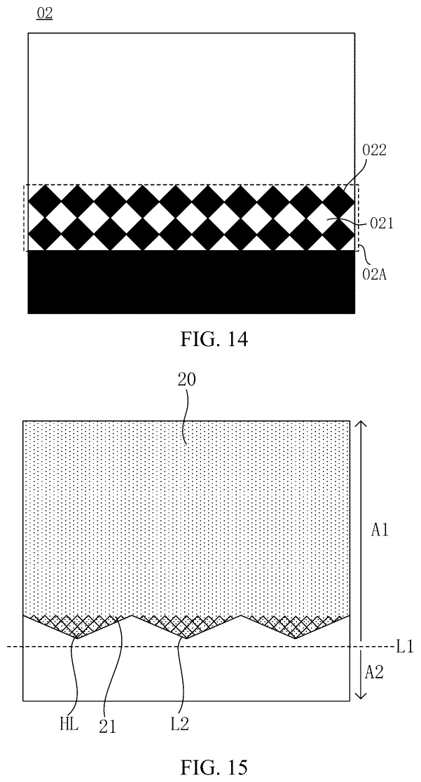

FIG. 13 is a schematic diagram showing a partial structure of a display panel according to an embodiment of the present disclosure, and FIG. 14 is a schematic diagram of a mask plate corresponding to the structure shown in FIG. 13.

In an embodiment, as shown in FIG. 13, the plurality of grooves HL are arranged in a checkerboard form. The grooves HL arranged in the checkerboard form may increase the obstruction of the light-shielding layer 30 when the light-shielding layer 30 overflows from the first organic encapsulation layer 20.

In addition, the thinning design of the first portion 201 relative to the second portion 202 may be realized by using a semi-gray mask plate 02. That is, as shown in FIG. 14, when the first organic encapsulation layer 20 is exposed, a light leakage portion 021 and the light-shielding portion 022 of an area 02A corresponding to the first portion 201 in the mask plate 02 may be arranged in the checkerboard form to adjust the proportion of the light leakage area of the area, for example, the light leakage area of the area 02A is less than or equal to 60%. When the first organic encapsulation layer 20 is the negative photosensitive layer, a position where the first organic encapsulation layer 20 overlaps the light-shielding portion 022 in the area 02A may receive a part of light due to a light diffraction phenomenon, and therefore, the groove HL formed at this position may not penetrate through the first organic encapsulation layer 20. In addition, the groove HL that prevents the light-shielding layer 30 from overflowing may be obtained while the thickness of the first portion 201 is thinned by using the mask plate 02 as shown in FIG. 14.

FIG. 15 is a schematic diagram showing a partial structure of a display panel according to an embodiment of the present disclosure.

When the first edge L2 includes a plurality of first protrusions 21, the first portion 201 includes the first protrusion 21, the first protrusions 21 may be at least a part of the first portion 201. Then, as shown in FIG. 15, when the surface of the first portion 201 away from the light-emitting layer 10 includes a plurality of grooves HL, at least a part of the grooves HL is located on the surface of the first protrusion 21 away from the light-emitting layer 10.

In addition, when the second edge L3 includes the plurality of second protrusions 22, the first portion 201 includes the second protrusion 22, the second protrusion 22 may be a part of the first portion 201, for example, the first protrusion 21 and the second protrusion 22 are the first portion 201. When the surface of the first portion 201 away from the light-emitting layer 10 includes a plurality of grooves HL, a part of the grooves HL are located on the surface of the second protrusion 22 away from the light-emitting layer 10, for example, the surfaces of the first protrusion 21 and the second protrusion 22 away from the light-emitting layer 10 both include the groove HL.

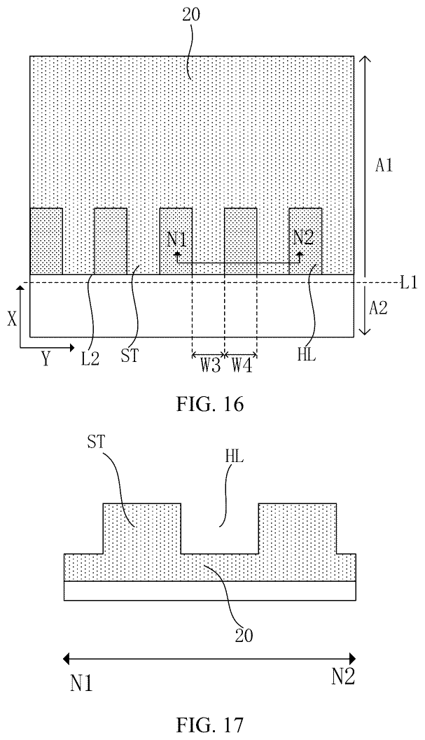

FIG. 16 is a schematic diagram showing a partial structure of a display panel according to an embodiment of the present disclosure, and FIG. 17 is a schematic cross-sectional view along line N1-N2 in FIG. 16 according to an embodiment of the present disclosure.

According to an embodiment of the present disclosure, Referring to FIG. 16 and FIG. 17, the first portion 201 includes a plurality of sawteeth ST. That is, the first portion 201 includes a plurality of valleys and peaks alternately arranged along the second direction Y, and in the process of spreading of the light-shielding layer 30, the peaks of the first portion 201 spread toward the valleys. Therefore, a position where the crack 32 of the light-shielding layer 30 appears is mainly near a position where the valleys and the peaks of the first portion 201 intersect. That is, a plurality of small cracks 32 arranged along the arrangement direction of the valleys and the peaks will appear in the light-shielding layer 30. If the small cracks 32 overlaps the metal structures 100 or the like reflecting light below the small cracks 32, the light reflected by the small cracks 32 may be regarded as point light arranged along the arrangement direction of the valleys and the peaks, which is beneficial to shadow elimination from the metal structures 100 or the like reflecting light.

In an embodiment, as shown in FIG. 17, the gap (valley) between the sawteeth ST does not penetrate through the first organic encapsulation layer 20, so the gap (valley) between the sawteeth ST may be regarded as the groove HL to reduce the step between the valleys and the peaks, thereby reducing a risk that the cracks 32 occurs near the boundary position between the valleys and the peaks in the light-shielding layer 30.

In an embodiment, a gap (valley) between the sawteeth ST may also penetrate through the first organic encapsulation layer 20, and the gap between the sawteeth ST may accommodate more of the light-shielding layer 30 that overflows beyond the first organic encapsulation layer 20, thereby further reducing a risk that the light-shielding layer 30 overflows to the second area A2.

A width W3 of the sawtooth ST is less than or equal to 10 μm, and/or a distance W4 between adjacent sawteeth ST is less than or equal to 10 μm.

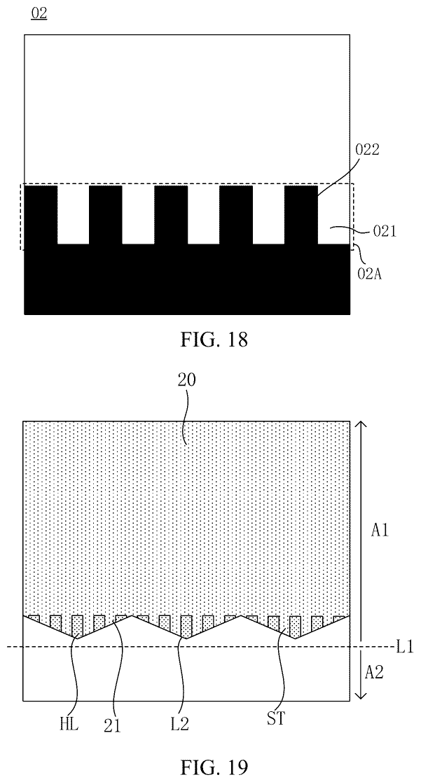

FIG. 18 is a schematic diagram of a mask plate corresponding to the structure shown in FIG. 16 according to an embodiment of the present disclosure.

In order to make the first portion 201 include a plurality of sawteeth ST, the plurality of light leakage portions 021 and the plurality of light-shielding portions 022 of the mask plate 02 corresponding to the area 02A of the first portion 201 are alternately arranged. In addition, a width of the light leakage portion 021 is less than or equal to 10 μm and/or a width of the light-shielding portion 022 is less than or equal to 10 μm. When the width of the light leakage portion 021 is less than or equal to 10 μm, the width of the sawtooth ST is less than or equal to 10 μm, so that it facilitates to form the first portion 201 with thinned thickness. When the width of the light-shielding portion 022 is less than or equal to 10 μm, the light-shielding portion 022 also receives a part of light due to a diffraction phenomenon, so that it facilitates to form the groove HL of the non-penetrative first organic encapsulation layer 20 between the sawteeth ST. In addition, the proportion of the light leakage area of the area 02A corresponding to the first portion 021 in the mask plate 02 may be adjusted by controlling the width of the light-shielding portion 022 and the width of the transparent portion 021, for example, the light leakage area of the area 02A is less than or equal to 60%, and when the first organic encapsulation layer 20 is the negative photosensitive layer, it facilitates to realize thinning of the thickness of the first portion 201.

FIG. 19 is a schematic diagram showing a partial structure of a display panel according to an embodiment of the present disclosure.

When the first edge L2 includes a plurality of first protrusions 21, the first portion 201 includes the first protrusion 21, the first protrusions 21 may be at least a part of the first portion 201. Then, as shown in FIG. 19, when the first portion 201 includes a plurality of sawteeth ST, at least a part of the sawteeths ST are located on the first protrusion 21.

In addition, when the second edge L2 includes a plurality of second protrusions 22, the first portion 201 includes the second protrusion 22, the second protrusion 22 may be a part of the first portion 201, for example, the first protrusion 21 and the second protrusion 22 are the first portion 201. Then, when the first portion includes a plurality of sawteeth ST, a part of the sawteeths ST is located on the second protrusion 22, for example, both the first protrusion 21 and the second protrusion include the sawteeth ST.

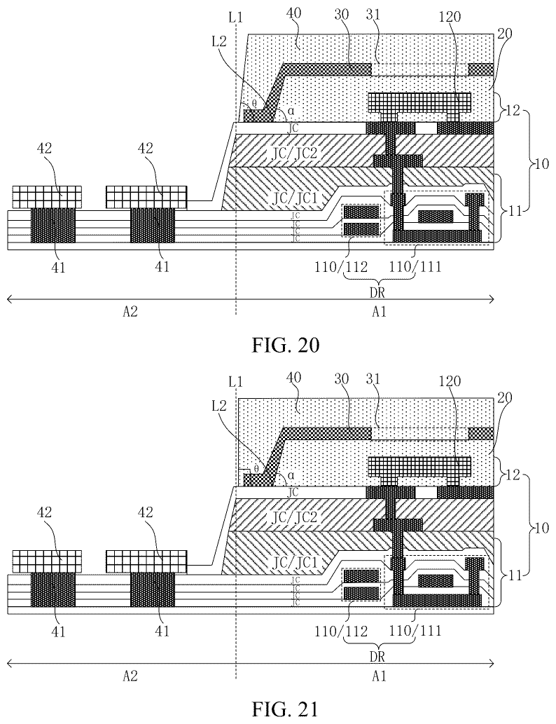

FIG. 20 is a partial cross-sectional view of a display panel according to an embodiment of the present disclosure.

According to an embodiment of the present disclosure, as shown in FIG. 20, the display panel 01 further includes a second organic encapsulation layer 40, the second organic encapsulation layer 40 is located on a side of the light-shielding layer 30 away from the first organic encapsulation layer 20, and the second organic encapsulation layer 40 encapsulates the light-shielding layer 30. The hollow portion 31 of the light-shielding layer 30 may be filled with the color resist (not shown), the color resist may filter light emitted by the light-emitting device 120 to obtain light with more pure chromaticity, the color resist may also filter ambient light entering the display panel 01 to weaken reflection of the ambient light by the display panel 01, and the second organic encapsulation layer 40 may also encapsulate and protect the color resist.

According to embodiments of the present disclosure, the second organic encapsulation layer 40 covers the edge of the first organic encapsulation layer 20. Since the edge of the first organic encapsulation layer 20 is retracted relative to the outer boundary L1 of the first area A1, the second organic encapsulation layer 40 covers the edge of the first organic encapsulation layer 20, so the first organic encapsulation layer 20 and the second organic encapsulation layer 40 are treated as a whole, and the edge of the organic encapsulation layer located above the light-emitting layer 10 may extend to the outer boundary L2. The arrangement of the second organic encapsulation layer 20 may make the first area A1 and the second area A2 have a more regular boundary. When the first organic encapsulation layer 20 includes the first protrusion 21, the second organic encapsulation layer 20 may not only cover the edge of the first organic encapsulation layer 20, but also may have a straight line shape.

The first organic encapsulation layer 20 and the second organic encapsulation layer 40 may be made of a same material, so that the first organic encapsulation layer 20 and the second organic encapsulation layer 40 may be prepared by substantially the same process, and the process difficulty is low; and since a refractive index of the first organic encapsulation layer 20 is the same as a refractive index of the second organic encapsulation layer 40, the light loss of the light emitted by the light-emitting device 120 when passing through the first organic encapsulation layer 20 and the second organic encapsulation layer 40 is low.

In addition, the second organic encapsulation layer 40 may further cover the edge of the light-shielding layer 30, and the second organic encapsulation layer 40 is also used to protect the light-shielding layer 30.

As shown in FIG. 20, an inclination angle of the side surface of the second organic encapsulation layer 40 is θ, and θ>α. That is, the inclination angle θ of the side surface of the second organic encapsulation layer 40 is greater than an inclination angle α of the side surface of the first organic encapsulation layer 20. If the inclination angle of the side surface of the encapsulation layer above the light-emitting layer 10 is relatively small, the width of the side surface in the arrangement direction of the first area A1 and the second area A2 is relatively large, and in order to prevent the light-emitting device 120 from being affected by the side surface, the light-emitting device 120 and the second area A2 need to be designed to avoid, which causes a distance between the light-emitting device 120 and the second area A2 to be increased and affects the display area of the display panel 01. When the first organic encapsulation layer 20 and the second organic encapsulation layer 40 are treated as a whole, the inclination angle of the side surface of the organic encapsulation layer located above the light-emitting layer 10 is the side surface of the second organic encapsulation layer 40. That is, the inclination angle of the side surface of the encapsulation layer located above the light-emitting layer 10 is relatively large, which may relieve the above problems.

FIG. 21 is a partial cross-sectional view of a display panel according to an embodiment of the present disclosure.

In an embodiment, as shown in FIG. 21, the inclination angle θ of the side surface of the second organic encapsulation layer 40 is 90°. The influence of the side surface of the organic encapsulation layer above the light-emitting layer 10 on the display area of the display panel 01 may be more effectively reduced, and a width of the frame of the display panel 01 may be effectively reduced. In addition, when the display panel 01 is used for the splicing screen, the visibility of a seam of the splicing screen may be weakened.

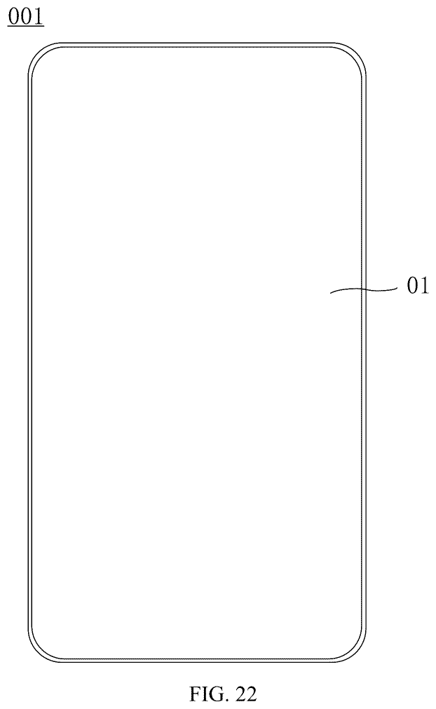

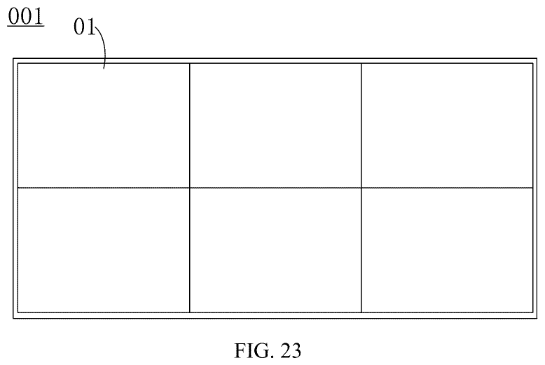

FIG. 22 is a schematic diagram of a display device according to an embodiment of the present disclosure, and FIG. 23 is a schematic diagram of a display device according to another embodiment of the present disclosure.

As shown in FIG. 22, an embodiment of the present disclosure further provides a display device 001, including the display panel 01 provided by any of the above embodiments. The display device 001 shown in FIG. 22 is merely illustrative, and the display device 001 may be any electronic device having a display function, such as a mobile phone, a tablet computer, a laptop computer, an electronic paper book, or a television. As shown in FIG. 23, the display device is a spliced display device including the display panel 01.

In the display device 001 provided by an embodiment of the present disclosure, there is a reduced risk of the light-shielding layer 30 remaining in the area corresponding to the second area A2 of the display panel 01, thereby increasing the process yield. When the display device 001 is a spliced display device, a risk of process failure in the second area A2 due to the light-shielding layer 30 flows to the second area A2 is reduced, and therefore, the width of the second area A2 may be narrowed, thereby reducing the visibility of the seam.

The above are merely exemplary embodiments of the present disclosure, which, as mentioned above, are not used to limit the present disclosure. Whatever within the principles of the present disclosure, including any modification, equivalent substitution, improvement, etc., shall fall into the protection scope of the present disclosure.

What is claimed is:

1. A display panel, comprising:
a first area and a second area, wherein the second area is located on a side of the first area adjacent to an edge of the display panel, and the first area comprises an outer boundary adjacent to the second area;
a light-emitting layer, comprising an array layer, a light-emitting device layer, and a plurality of insulating layers, wherein the array layer comprises a plurality of driving devices and the light-emitting device layer comprises a plurality of light-emitting devices located in the first area; the first area comprises a part of one of the plurality of insulating layers and the second area does not comprise the part of the one of the plurality of insulating layers;
a first organic encapsulation layer located on a side of the light-emitting device layer away from the array layer, wherein the first organic encapsulation layer encapsulates the plurality of light-emitting devices; and
a light-shielding layer located on a side of the first organic encapsulation layer away from the light-emitting layer, wherein the light-shielding layer comprises a plurality of hollow portions, and the plurality of hollow portions expose the plurality of light-emitting devices;
wherein, the first organic encapsulation layer comprises a first edge adjacent to the second area, the first edge is located on a side of the outer boundary away from the second area, and a distance between the first edge and the outer boundary is d, where d>0.

2. The display panel according to claim 1, wherein the second area comprises a plurality of pins electrically connected to a circuit board.

3. The display panel according to claim 1, wherein an inclination angle of a side surface of the first organic encapsulation layer is less than 90°.

4. The display panel according to claim 1, wherein the light-shielding layer covers an edge of the first organic encapsulation layer.

5. The display panel according to claim 1, wherein the first edge comprises a first protrusion protruding away from the first area.

6. The display panel according to claim 5, wherein an inner angle of the first protrusion is greater than or equal to 150°.

7. The display panel according to claim 6, wherein the first edge further comprises a second protrusion protruding away from the first area, and a morphology of the second protrusion is different from a morphology of the first protrusion.

8. The display panel according to claim 7, wherein an inner angle of the second protrusion is less than or equal to the inner angle of the first protrusion; or
wherein a width of the second protrusion along a second direction is less than a width of the first protrusion along the second direction, the second direction is perpendicular to a first direction, and the first direction is parallel to a direction of a plane of the display panel and is parallel to an arrangement direction of the first area and the second area; or
wherein a length of the second protrusion along a first direction is less than a length of the first protrusion along the first direction, and the first direction is parallel to the direction of a plane of the display panel and is parallel to the arrangement direction of the first area and the second area.

9. The display panel according to claim 7, wherein the first protrusion overlaps the light-emitting device in a first direction, and the first direction is parallel to a direction of a plane of the display panel and is parallel to an arrangement direction of the first area and the second area; or
wherein the second protrusion is misaligned with the light-emitting device in a first direction, and the first direction is parallel to a direction of the plane where the display panel is located and is parallel to the arrangement direction of the first area and the second area.

10. The display panel according to claim 5, further comprising a third area, wherein the first organic encapsulation layer further comprises a second edge adjacent to the third area; and
wherein the second edge comprises a third protrusion, the third protrusion protrudes away from the first area along a second direction, and the second direction is parallel to a plane of the display panel and is perpendicular to an arrangement direction of the third area and the first area.

11. The display panel according to claim 1, wherein the first organic encapsulation layer comprises a first portion and a second portion, the second portion is located in the first area, and the first portion is located on a side of the second portion facing the second area; and
wherein a thickness of the first portion is less than a thickness of the second portion.

12. The display panel according to claim 11, wherein the first portion comprises a first sub-portion and a second sub-portion, and the first sub-portion is located on a side of the second sub-portion facing the second area; and
wherein a thickness of the first sub-portion is less than a thickness of the second sub-portion.

13. The display panel according to claim 11, wherein a surface of the first portion away from the light-emitting layer comprises a plurality of grooves.

14. The display panel according to claim 13, wherein a distance between the groove and the light-emitting device is greater than or equal to 5 μm in a direction parallel to a plane of the display panel.

15. The display panel according to claim 13, wherein the plurality of grooves are arranged in a checkerboard form; or
wherein the first portion comprises a plurality of sawteeth.

16. The display panel according to claim 1, further comprising a second organic encapsulation layer located on a side of the light-shielding layer away from the first organic encapsulation layer;
wherein the second organic encapsulation layer covers an edge of the first organic encapsulation layer.

17. The display panel according to claim 16, wherein an inclination angle of a side surface of the second organic encapsulation layer is greater than an inclination angle of a side surface of the first organic encapsulation layer.

18. The display panel according to claim 16, wherein an inclination angle of the side surface of the second organic encapsulation layer is 90°.

19. The display panel according to claim 16, wherein the second organic encapsulation layer covers an edge of the light-shielding layer.

20. A display device, comprising a display panel, wherein the display panel comprises:
a first area and a second area, wherein the second area is located on a side of the first area adjacent to an edge of the display panel, and the first area comprises an outer boundary adjacent to the second area;
a light-emitting layer, comprising an array layer, a light-emitting device layer, and a plurality of insulating layers, wherein the array layer comprises a plurality of driving devices and the light-emitting device layer comprises a plurality of light-emitting devices located in the first area; the first area comprises a part of one of the plurality of insulating layers and the second area does not comprise the part of the one of the plurality of insulating layers;
a first organic encapsulation layer located on a side of the light-emitting device layer away from the array layer, wherein the first organic encapsulation layer encapsulates the plurality of light-emitting devices; and
a light-shielding layer located on a side of the first organic encapsulation layer away from the light-emitting layer, wherein the light-shielding layer comprises a plurality of hollow portions, and the hollow portions expose the plurality of light-emitting devices;
wherein, the first organic encapsulation layer comprises a first edge adjacent to the second area, the first edge is located on a side of the outer boundary away from the second area, and a distance between the first edge and the outer boundary is d, where d>0.
